(19) United States
(12) Patent Application Publication
(10) Pub. No.: US 2013/0078789 A1
(43) Pub. Date: Mar. 28, 2013

(54) Substrate Processing Apparatus, Method of Manufacturing Semiconductor Device and Non-Transitory Computer-Readable Recording Medium

(71) Applicant: Hitachi Kokusai Electric Inc., Tokyo (JP)

(72) Inventor: Masanori Nakayama, Toyama (JP)

(73) Assignee: HITACHI KOKUSAI ELECTRIC INC., Toyko (JP)

(21) Appl. No.: 13/622,595

(22) Filed: Sep. 19, 2012

(30) Foreign Application Priority Data
Sep. 22, 2011 (JP) 2011-207452
Aug. 28, 2012 (JP) 2012-187884

(51) Int. Cl. C23C 16/50; H01L 21/223

(52) U.S. Cl. 438/513; 118/723 R; 118/723 E; 118/697; 257/E21.143

(57) ABSTRACT

A substrate processing apparatus includes a process chamber accommodating a substrate including a thin film formed at a film-forming temperature; a gas supply unit for supplying a process gas including oxygen and/or nitrogen onto the substrate; an excitation unit for exciting the process gas supplied into the process chamber; a heating unit for heating the substrate; an exhaust unit for exhausting an inside of the process chamber; and a control unit for controlling the gas supply unit, the excitation unit, the heating unit and the exhaust unit such that a temperature of the substrate is equal to or lower than the film-forming temperature when the substrate is processed by heating the substrate by the heating unit, exciting the process gas supplied from the gas supply unit by the excitation unit, and supplying the process gas excited by the excitation unit onto a surface of the substrate.

### CROSS REFERENCE TO RELATED APPLICATIONS

This application claims foreign priority under 35 U.S.C. §119(a)-(d) to Japanese Patent Application Nos. 2011-207452 and 2012-187884 filed on Sep. 22, 2011 and Aug. 28, 2012, respectively, entitled “Substrate Processing Apparatus, Method of Manufacturing Semiconductor Device and Non-Transitory Computer-Readable Recording Medium,” the entire contents of each of which are hereby incorporated by reference.

### FIELD OF THE INVENTION

The present invention relates to a substrate processing apparatus for processing a substrate using an excited process gas, a method of manufacturing a semiconductor device and a non-transitory computer-readable recording medium.

### BACKGROUND

A method of manufacturing a semiconductor device, e.g., a dynamic random access memory (DRAM), is performed, for example, using a substrate processing apparatus by chemical vapor deposition (CVD). The substrate processing apparatus includes, for example, a process chamber into which a substrate is loaded; a heating unit configured to heat the substrate; and an excitation unit configured to excite a process gas supplied into the process chamber. By exciting the process gas supplied into the process chamber by the excitation unit, the process gas is supplied onto the substrate to perform thermal treatment for forming a thin film on the substrate. In general, when various thin films used in semiconductor devices are formed at high temperatures, device characteristics or electrical characteristics are improved. Accordingly, the heating unit heats the substrate to 750° C. or higher.

### SUMMARY

Recently, as the structures of devices have become finer and finer, regulations on thermal budgets have become tightened, and a process of manufacturing a semiconductor device is more likely to be performed at low temperatures. Thus, research has been actively conducted on a method of forming, for example, an oxide film on a substrate at a low temperature, for example, 650° C. or less, by CVD. Accordingly, the quality of films has been improved.

However, the quality and electrical characteristics of a thin film formed on a substrate at a low temperature by CVD are lower than those of a thermal oxide film or a radical oxide film formed at a high temperature. This is because when a thin film is processed at a low temperature, many impurities such as hydrogen atoms or carbon atoms contained in a process gas or a material for forming a film, may remain in the thin film. Furthermore, defects may occur at an interface between the thin film and the substrate or a bulk of the thin film, and may be changed into holes or traps.

The present invention provides a substrate processing apparatus capable of improving the quality of a thin film formed on a substrate by forming the thin film at a low temperature, a method of manufacturing a semiconductor device and a computer program.

According to an aspect of the present invention, there is provided a substrate processing apparatus including: a process chamber accommodating a substrate including a thin film formed at a predetermined film-forming temperature; a gas supply unit configured to supply a process gas including at least one of oxygen and nitrogen to the substrate in the process chamber; an excitation unit configured to excite the process gas supplied into the process chamber; a heating unit configured to heat the substrate in the process chamber; an exhaust unit configured to exhaust an inside of the process chamber; and a control unit configured to control at least the gas supply unit, the excitation unit, the heating unit and the exhaust unit in a manner that a temperature of the substrate is equal to or lower than the film-forming temperature when the substrate is processed by heating the substrate by the heating unit, exciting the process gas supplied from the gas supply unit by the excitation unit, and supplying the process gas excited by the excitation unit to a surface of the substrate.

According to another aspect of the present invention, there is provided a method of manufacturing a substrate, including: loading a substrate into a process chamber, the substrate having a thin film thereon formed at a predetermined film-forming temperature; and processing the substrate by heating the substrate to a temperature equal to or lower than the predetermined film-forming temperature, supplying a process gas including at least one of oxygen and nitrogen to the substrate, and exciting the process gas supplied to the substrate.

According to still another aspect of the present invention, there is provided a non-transitory computer-readable recording medium having a program to be executed by a computer: heating a substrate accommodated in a process chamber having thereon a thin film formed at a predetermined film-forming temperature to a temperature equal to or lower than the predetermined film-forming temperature; and supplying a process gas including at least one of oxygen and nitrogen to the substrate, and exciting the process gas supplied to the substrate; and an exhausting step for exhausting an inside of the process chamber.

### BRIEF DESCRIPTION OF THE DRAWINGS

FIG. 1 is a schematic cross-sectional view of a substrate processing apparatus according to an embodiment of the present invention.

FIG. 2 is a flowchart illustrating a process of processing a substrate according to an embodiment of the present invention.

FIG. 3 is a graph illustrating a result of evaluating an etching rate of a silicon oxide (SiO₂) film when etching was performed using dilute hydrofluoric acid (DHF) under various conditions.

FIG. 4 is a graph illustrating a ratio between the numbers of oxygen atoms and silicon atoms in a silicon oxide (SiO2) film, obtained by analyzing the silicon oxide (SiO₂) film on a substrate-processed wafer through X-ray photoelectron spectroscopy (XPS) under various conditions.

FIG. 5 is a graph illustrating a full width at half maximum of a peak value of each of the 2p orbital of silicon atoms and the 1s orbital of oxygen atoms in a silicon oxide (SiO2) film, obtained by analyzing the silicon oxide (SiO₂) film on a substrate-processed wafer through XPS under various conditions.

FIG. 6 is a graph illustrating the concentration of impurities obtained by measuring a silicon oxide (SiO₂) film of a wafer formed under various conditions through secondary ion mass spectrometry (SIMS).

FIG. 7 is a graph illustrating the defect density of a silicon oxide (SiO₂) film under various conditions.

FIG. 8 is a schematic cross-sectional view of a substrate processing apparatus including a lamp heating unit according to another embodiment of the present invention.

FIG. 9 is a schematic cross-sectional view of an inductively coupled plasma (ICP)-based plasma processing apparatus which is a substrate processing apparatus according to another embodiment of the present invention.

FIG. 10 is a schematic cross-sectional view of an electron cyclotron resonance (ECR)-based plasma processing apparatus which is a substrate processing apparatus according to still another embodiment of the present invention.

FIG. 11 is a schematic block diagram of a controller included in a substrate processing apparatus which may be used in an embodiment of the present invention.

### DETAILED DESCRIPTION

Hereinafter, exemplary embodiments of the present invention will be described with reference to the appended drawings.

### (1) Configuration of Substrate Processing Apparatus

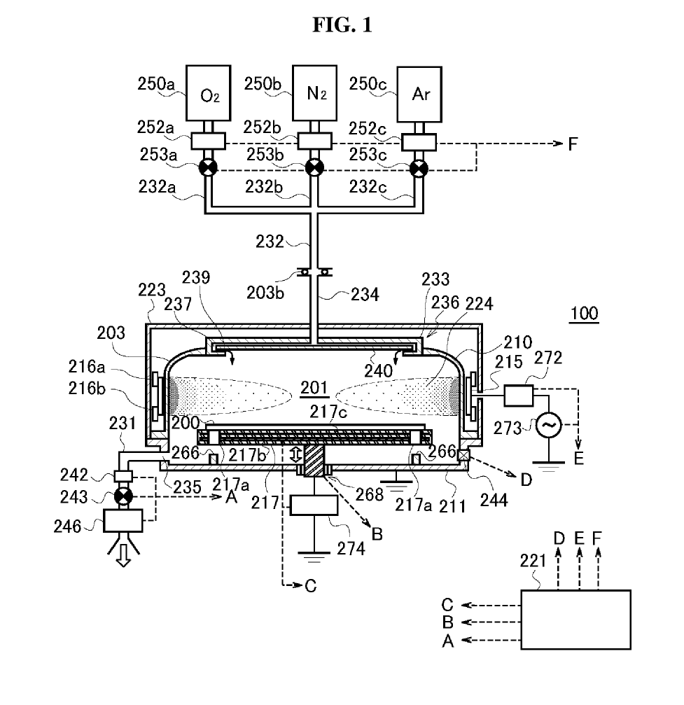

First, a substrate processing apparatus according to an embodiment of the present invention will be described with reference to FIG. 1. FIG. 1 is a schematic cross-sectional view of a substrate processing apparatus 100 configured as a modified magnetron type (MMT) device.

The MMT device is a device that plasma-processes a wafer 200, which is a substrate made of, for example, silicon, using an MMT plasma source for generating high-density plasma using an electric field and a magnetic field. The MMT device may perform various plasma processes, e.g., oxidizing or nitriding a surface of the wafer 200 or a thin film formed on the wafer 200, forming a thin film on the wafer 200, or etching a surface of the wafer 200, by exciting a process gas to a plasma state.

The MMT device is capable of efficiently generating plasma even when the frequency of high-frequency power applied thereto is about one tenth of the frequency of high-frequency power used in a general plasma device. Thus, it is possible to reduce damage to a process chamber 201 in which plasma is generated, and suppress generation of particles. Furthermore, the wafer 200, the thickness of which ranges from about 2 nm to about 15 nm may be processed by controlling application of a bias voltage to a susceptor 217, which will be described below, without greatly changing plasma conditions, e.g., pressure or power supply. Also, the wafer 200 may be heated to room temperature to 700° C. using a heater 217b included in the susceptor 217. Based on such features of the MMT device, substrate processing (modification) may be performed on the thin film formed on the wafer 200 at a low temperature, for example, at 650° C. or less by chemical vapor deposition (CVD) while controlling a heating temperature of the wafer 200 or the thickness of the thin film.

### Process Chamber

A process container 203 forming the process chamber 201 of the substrate processing apparatus 100 according to the present embodiment includes an upper container 210 which is a dome-type first container and a lower container 211 which is an bowl-type second container. The process chamber 201 is formed by covering the lower container 211 with the upper container 210. The upper container 210 is made of, for example, a non-metallic material such as aluminum oxide (Al₂O₃) or quartz (SiO₂), and the lower container 211 is made of, for example, aluminum (Al).

A gate valve 244 that acts as a partition valve is installed on a sidewall of the lower container 211. When the gate valve 244 is opened, the wafer 200 may be loaded into or unloaded from the process chamber 201 using a transfer mechanism (not shown). By closing the gate valve 244, the inside of the process chamber 201 may be tightly blocked.

### Substrate Support

The susceptor 217 acting as a substrate support for supporting the wafer 200 is located on a lower central portion of the process chamber 201. The susceptor 217 is made of, for example, a non-metallic material such as aluminum nitride (AlN), ceramics, or quartz, in order to suppress metallic pollution of the wafer 200. Also, the susceptor 217 is electrically insulated from the lower container 211.

An impedance control electrode 217c is installed in the susceptor 217 to change impedance. The impedance control electrode 217c is installed via an impedance control device 274. The impedance control device 274 includes coil or a variable condenser. By controlling the number of turns of the coil or the capacitance of the variable condenser, an electric potential of the wafer 200 may be controlled via the impedance control electrode 217c and the susceptor 217. Also, the impedance control device 274 is electrically connected to a controller 221 which will be described in detail below.

In the susceptor 217, a susceptor lift device 268 is installed to move the susceptor 217 upward/downward. Through-holes 217a are installed to pass through the susceptor 217. At least three wafer lift pins 266 are installed on a lower surface of the lower container 211 to move the wafer 200 upward/downward. The through-holes 217a and the wafer lift pins 266 are disposed in such a manner that the wafer lift pins 266 may pass through the through-holes 217a not to contact the susceptor 217 when the susceptor 217 is moved downward by the susceptor lift device 268.

### Heating Unit

The heater 217b acting as a heating unit is embedded in the susceptor 217 to be integrally formed with the susceptor 217, and may heat the wafer 200. When power is supplied to the heater 217b, a surface of the wafer 200 is heated to a predetermined temperature, e.g., room temperature to about 700° C. Also, a temperature sensor (not shown) is installed in the susceptor 217. The heater 217b and the temperature sensor are electrically connected to the controller 221 which will be described in detail below. The controller 221 is configured to control supply of power to the heater 217b based on temperature information detected by the temperature sensor.

### Gas Supply Unit

Above the process chamber 201, a shower head 236 is installed to supply a process gas into the process chamber 201. The shower head 236 includes a cap-shaped lid 233, a gas introduction unit 234, a buffer chamber 237, a shielding plate 240 and a gas outlet 239.

The lid 233 is installed to air-tightly seal an opening formed in an upper surface of the upper container 210. The shielding plate 240 is installed under the lid 233. The buffer chamber 237 is a space defined between the lid 233 and the shielding plate 240. The buffer chamber 237 acts as a dispersion space for dispersing a process gas introduced from the gas introduction unit 234. The process gas passing through the buffer chamber 237 is supplied into the process chamber 201 through the gas outlet 239 disposed at a side of the shielding plate 240. An opening is formed in the lid 233. A downstream end of the gas introduction unit 234 is air-tightly installed in the opening formed in the lid 233. An upstream end of the gas introduction unit 234 is connected to a downstream end of a gas supply tube 232, via an O-ring 203b acting as an sealing member.

An upstream side of the gas supply tube 232 is connected to a downstream end of an oxygen-containing gas supply tube 232a for supplying O₂ gas, which is a gas containing oxygen atoms acting as a process gas (hereinafter referred to as an ‘oxygen-containing gas’), a downstream end of a nitrogen-containing gas supply tube 232b for supplying N₂ gas, which is a gas containing nitrogen atoms acting as process gas (hereinafter referred to as a ‘nitrogen-containing gas’), and a downstream end of a dilute gas supply tube 232c for supplying a rare gas acting as an inert gas, e.g., argon (Ar) gas. Each of the gas supply tube 232, the oxygen-containing gas supply tube 232a, the nitrogen-containing gas supply tube 232b and the rare gas supply tube 232c is made of, for example, a non-metallic material such as quartz or aluminum oxide, or a metallic material such as SUS.

An oxygen gas supply source 250a, a mass flow controller 252a acting as a flow rate controller and a valve 253a which is a switch valve from an upstream side are sequentially connected to the oxygen-containing gas supply tube 232a. A nitrogen gas supply source 250b, a mass flow controller 252b acting as a flow rate controller, and a valve 253b which is a switch valve from an upstream side are sequentially connected to the nitrogen-containing gas supply tube 232b. An argon (Ar) gas supply source 250c, a mass flow controller 252c acting as a flow rate controller and a valve 253c which is a switch valve from an upstream side are sequentially connected to the rare gas supply tube 232c.

The mass flow controllers 252a to 252c and the valves 253a to 253c are electrically connected to the controller 221 which will be described in detail below. The controller 221 is configured to control the mass flow controllers 252a to 252c and the valve 253a to 253c to be open/closed so that the flow rate of a gas supplied to the process chamber 201 becomes equal to a predetermined flow rate. As described above, desired amounts of at least one of oxygen (O₂) gas and nitrogen (N₂) gas and argon (Ar) gas may be supplied into the process chamber 201 via the gas supply tube 232, the buffer chamber 237 and the gas outlet 239 while controlling a flow rate by the mass flow controllers 252a to 252c by opening/closing the valves 253a to 253c.

The gas supply unit according to the present embodiment is mainly constituted by the shower head 236, the O-ring 203b, the gas supply tube 232, the oxygen-containing gas supply tube 232a, the nitrogen-containing gas supply tube 232b, the rare gas supply tube 232c, the mass flow controllers 252a to 252c and the valves 253a through 253c. The oxygen gas supply source 250a, the nitrogen gas supply source 250b and the argon (Ar) gas supply source 250c may further be included in the gas supply unit.

### Exhaust Unit

A gas exhaust port 235 is installed on a lower sidewall of the lower container 211 to exhaust a process gas from the process chamber 201. The gas exhaust port 235 is connected to an upstream end of the gas exhaust tube 231 via which gas is exhausted. An APC 242 which is a pressure controller, a valve 243 which is a switch valve and a vacuum pump 246 which is an exhaust device from the upstream side are sequentially installed at the gas exhaust tube 231. The APC 242, the valve 243 and the vacuum pump 246 are electrically connected to the controller 221 which will be described below. The inside of the process chamber 201 may be exhausted by operating the vacuum pump 246 to open the valve 243. Also, a pressure sensor (not shown) is installed at the gas exhaust tube 231. The pressure sensor is electrically connected to the controller 221 which will be described below. Based on pressure information detected by the pressure sensor, the degree of opening of the APC 242 may be controlled to adjust pressure in the process chamber 201. The exhaust unit according to the present embodiment may is mainly constituted by the gas exhaust port 235, the gas exhaust tube 231, the APC 242 and the valve 243. The vacuum pump 246 may further be included in the exhaust unit.

### Excitation Unit

A tubular electrode 215 acting as a plasma generation electrode is installed on an outer circumference of the process container 203 (the upper container 210) to cover a plasma generating region 224 in the process chamber 201. The tubular electrode 215 has a tubular shape, e.g., a cylindrical shape. The tubular electrode 215 is connected to a high-frequency power source 273 that generates high-frequency power via an impedance matching device 272 that performs impedance matching. The tubular electrode 215 acts as a discharging device for exciting a process gas supplied onto a surface of the wafer 200 loaded into the process chamber 201.

An upper magnet 216a and a lower magnet 216b are installed on upper and lower portions of an outer surface of the tubular electrode 215, respectively. The upper magnet 216a and the lower magnet 216b each include a permanent magnet having a tubular shape, e.g., a ring shape. Each of the upper magnet 216a and the lower magnet 216b includes magnetic poles on both ends thereof, i.e., inner and outer circumferential ends of each of the upper magnet 216a and the lower magnet 216b, in a radius direction of the process chamber 201. Magnetic poles of the upper and lower magnets 216a and 216b are disposed to face each other such that the magnetic poles have polarities opposite to each other. In other words, the magnetic pole at the inner circumference of the upper magnet 216a has a polarity opposite to that of the magnetic pole at the inner circumference of the lower magnet 216b. Thus, a magnetic line of force is formed in a cylindrical direction along an inner surface of the tubular electrode 215.

At least one of oxygen (O₂) gas and nitrogen (N₂) gas is supplied into the process chamber 201. Then, high-frequency power is supplied to the tubular electrode 215 so as to generate an electric field at a location at which a magnetic field is generated by the upper magnet 216a and the lower magnet 216b. Thus, magnetron discharge plasma is generated in the plasma generating region 224 in the process chamber 201. In this case, since discharged electrons orbit due to the electric and magnetic fields, a rate of generating ionizing particles in plasma becomes high, thereby generating long-lifetime, high-density plasma.

The excitation unit according to the present embodiment may be mainly constituted by the tubular electrode 215, the upper magnet 216a and the lower magnet 216b. The impedance matching device 272 and the high-frequency power source 273 may be included in the excitation unit.

A metallic shielding plate 223 is installed around the tubular electrode 215, the upper magnet 216a and the lower magnet 216b to effectively shield an electric field and a magnetic field, so that an external environment or other devices, e.g., another treatment furnace, may not be interfered with by an electric field and a magnetic field formed by the tubular electrode 215, the upper magnet 216a and the lower magnet 216b.

### Control Unit

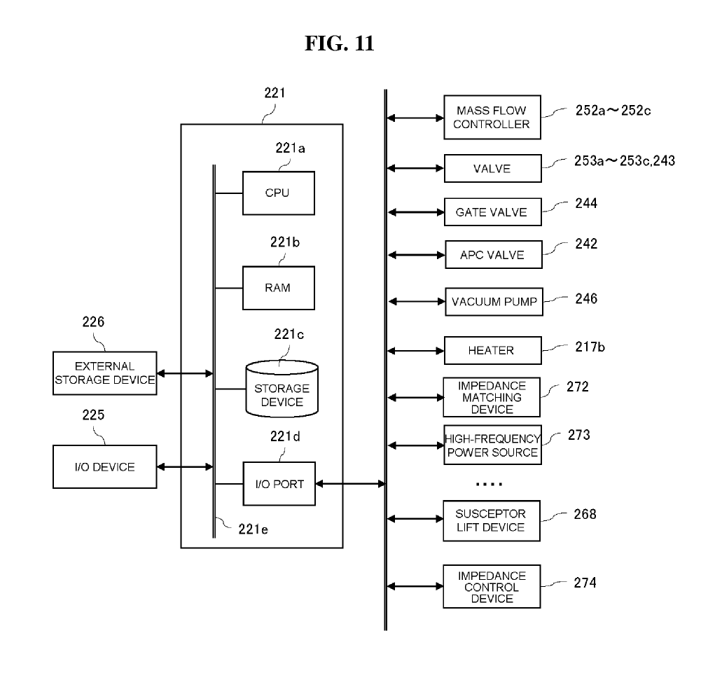

Referring to FIG. 11, the controller 221 which acts as a control unit is configured as a computer including a central processing unit (CPU) 221a, a random access memory (RAM) 221b, a storage device 221c and an input/output (I/O) port 221d. The RAM 221b, the storage device 221c and the I/O port 221d may exchange data with the CPU 221a via an internal bus 221e. The controller 221 may be connected to an I/O device 225, for example, a touch panel, a mouse, a keyboard, a manipulation terminal, etc. The controller 221 may be connected to, for example, a display unit (not shown) that displays an image.

Examples of the storage device 221c may include a flash memory, a hard disk drive (HDD), a compact disc-read only memory (CD-ROM), and so on. In the storage device 221c, a control program for controlling an operation of the substrate processing apparatus 100 or a process recipe instructing an order or conditions of processing a substrate are stored to be readable. The process recipe may act as a program, and allows the controller 221 to perform operations included in a substrate processing step which will be described below, thereby obtaining a desired result. Hereinafter, such a process recipe and a control program will be referred to together simply as a ‘program.’ Also, in the present disclosure, the term ‘program’ should be understood as including at least one of a process recipe and a control program. The RAM 221b is configured as a work area for temporarily storing a program or data read by the CPU 221a.

The I/O port 221d is connected to the mass flow controllers 252a to 252c, the valves 253a to 253c, the valve 243, the gate valve 244, the APC valve 242, the vacuum pump 246, the heater 217b, the impedance matching device 272, the high-frequency power source 273, the susceptor lift device 268 and the impedance control device 274 described above.

The CPU 221a reads the process recipe from the storage device 221c according to a manipulation command received via the I/O device 225 while reading and executing the control program from the storage device 221c. Also, according to the read process recipe, the CPU 221a controls the degree of opening of the APC valve 242, opening/closing of the valve 243 and driving/suspending of the vacuum pump 246 through a signal line A; controls moving of the susceptor lift device 268 upward/downward through a signal line B; controls an amount of power to be supplied to the heater 217b based on temperature information detected by the temperature sensor (temperature control) and adjusts an impedance by the impedance control device 274 through a signal line C; controls opening/closing of the gate valve 244 through a signal line D; controls operations of the impedance matching device 272 and the high-frequency power source 273 through a signal line E; and controls a flow rate of various gases using the mass flow controllers 252a to 252c and opening/closing of the valves 253a to 253c through a signal line F.

The controller 221 may be configured as either a personal computer or a general-purpose computer. For example, the controller 221 according to the present embodiment may be configured by preparing an external storage device 226 storing such programs, e.g., a magnetic disk (a magnetic tape, a flexible disk, a hard disk, etc.), an optical disc (a CD or a digital versatile disc (DVD), etc.), a magneto-optical disc (MO), or a semiconductor memory (a universal serial bus (USB) memory, a memory card, etc.), and then installing the programs on a general-purpose computer using the external storage device 226. However, a method of supplying a program to a computer is not limited to using the external storage device 226. For example, a communication unit, e.g., the Internet or an exclusive line, may be used to supply a program to a computer without having to use the external storage device 226. The storage device 221c or the external storage device 226 may be configured as a non-transitory computer-readable recording medium. Hereinafter, the storage device 221c and the external storage device 226 may also be referred to together simply as a ‘recording medium.’ Also, in the present disclosure, the term ‘recording medium’ should be understood as including at least one of the storage device 221c and the external storage device 226.

### (2) Substrate Processing Step

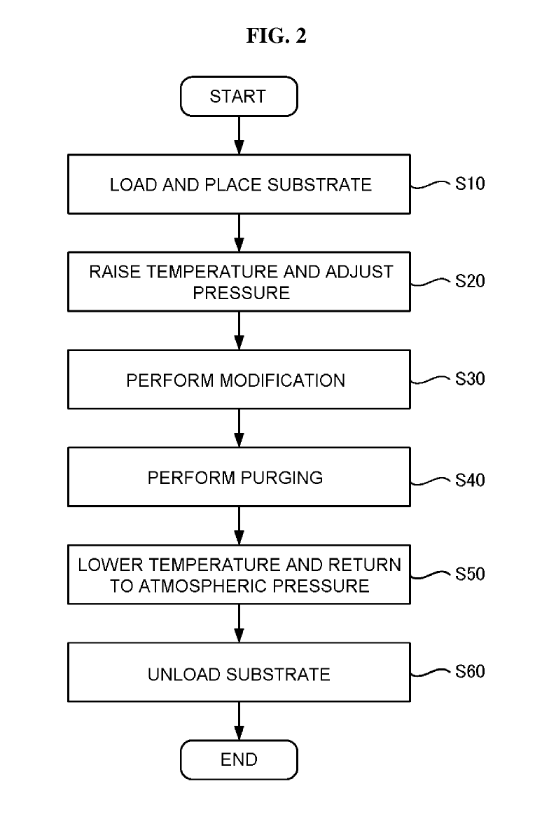

Next, a substrate processing step included in a semiconductor manufacturing method according to the present embodiment will be described with reference to FIG. 2. The substrate processing step is performed by the substrate processing apparatus 100 which is an MMT device described above. Here, a method of processing a wafer 200 including a silicon oxide (SiO₂) film, which is formed at a predetermined film-forming temperature, with plasma will be described. In other words, a method of modifying the silicon oxide (SiO₂) film formed on the wafer 200 to remove impurities from the silicon oxide (SiO₂) film will now be described. In the description below, operations of elements of the substrate processing apparatus 100 are controlled by the controller 221.

### Substrate Loading/Placing Process (Operation S10)

First, the susceptor 217 is moved downward to a location to which the wafer 200 is to be transferred, and the wafer lift pins 266 pass through the through-holes 217a of the susceptor 217. Thus, the lift pins 266 protrude by a predetermined height, compared to a surface of the susceptor 217. Then, the gate valve 244 is opened, and the wafer 200 is loaded into the process chamber 201 using a transfer mechanism (not shown). Thus, the wafer 200 is horizontally supported on the wafer lift pins 266 protruding compared to the surface of the susceptor 217.

A silicon oxide (SiO₂) film has been formed on the wafer 200 at a predetermined film-forming temperature by CVD. The silicon oxide (SiO₂) film is formed by heating the wafer 200 at a predetermined film-forming temperature or less, e.g., a low temperature of 650° C. or less using another CVD device (not shown) and a film-forming gas including an organic source gas such as tetraethoxysilane [Si(OC₂H₅)₄, abbreviation: TEOS] and oxygen (O₂) gas as an oxidization agent. Alternatively, the silicon oxide (SiO₂) film may be formed at a film-forming temperature within a low-temperature range by CVD without using the TEOS. When the silicon oxide (SiO₂) film is formed by CVD at the film-forming temperature within a low-temperature range, impurities including at least one of a carbon (C) atom, a hydrogen (H) atom, a nitrogen (N) atom and a chlorine (Cl) atom may remain in the silicon oxide (SiO₂) film. It is hereinafter assumed that a film-forming temperature for forming a thin film on the wafer 200 is, for example, 450° C.

When the wafer 200 is loaded into the process chamber 201, the transfer mechanism is disposed outside the process chamber 201, and then the gate valve 244 is closed to seal the inside of the process chamber 201. Then, the susceptor 217 is moved upward by the susceptor lift device 268. Thus, the wafer 200 is disposed on a surface of the susceptor 217. Then, the susceptor 217 is moved upward to a predetermined location so as to lift the wafer 200 to a predetermined process location.

When the wafer 200 is loaded into the process chamber 201, the inside of the process chamber 201 may be exhausted using the exhaust unit, and argon (Ar) gas acting as a purge gas may then be supplied into the process chamber 201 using the gas supply unit. In other words, argon (Ar) gas may be supplied into the process chamber 201 via the buffer chamber 237 by opening the valve 253c while exhausting the inside of the process chamber 201 by operating the vacuum pump 246 to open the valve 243. Thus, it is possible to prevent particles from penetrating into the process chamber 201 or from being adhered onto the wafer 200. Also, the vacuum pump 246 is continuously operated at least until substrate unloading (operation S60) which will be described below is performed, starting from the loading/placing of the substrate (operation S10).

### Raising Temperature/Pressure Adjusting Process (Operation S20)

Then, a surface of the wafer 200 is heated to the film-forming temperature of the thin film formed on the wafer 200 or less by supplying power to the heater 217b embedded in the susceptor 217. If a plurality of thin films have been formed on the wafer 200, the surface of the wafer 200 may be heated to no more than a lowest temperature among film-forming temperatures of the plurality of thin films. In this case, the temperature of the heater 217b is controlled by adjusting an amount of power to be supplied to the heater 217b based on temperature information detected by the temperature sensor (not shown).

If a surface of the wafer 200 is heated to be higher than the film-forming temperature of the thin film on the wafer 200, then impurity diffusion may occur in, for example, a source/drain region formed on the surface of the wafer 200. In this case, circuit characteristics may be degraded to lower the performance of the semiconductor device. By limiting the surface temperature of the wafer 200 as described above, it is possible to prevent impurities from being diffused into the source/drain region on the surface of the wafer 200, the circuit characteristics from being degraded, and the performance of the semiconductor device from being lowered. Also, as described above, since the film-forming temperature of the thin film on the wafer 200 is set to 450° C., it is hereinafter assumed that a surface of the wafer 200 is heated to the film-forming temperature of the thin film, e.g., 450° C.

The inside of the process chamber 201 is vacuum-exhausted by the vacuum pump 246 so that desired pressure, for example, 1 Pa to 260 Pa, or particularly, 10 Pa to 100 Pa, may be applied to the inside of the process chamber 201. In this case, the pressure in the process chamber 201 is measured by a pressure sensor (not shown), and the degree of opening of the APC 242 is feedback-controlled based on the measured pressure.

### Modification Process (Operation S30)

Here, for example, O₂ gas is used as a process gas.

First, oxygen (O₂) gas is supplied into the process chamber 201 via the buffer chamber 237 by opening the valve 253a and using the oxygen-containing gas supply tube 232a. In this case, the mass flow controller 252a controls the flow rate of the oxygen (O₂) gas to be equal to a predetermined flow rate.

When the oxygen (O₂) gas is supplied into the process chamber 201 as a process gas, argon (Ar) gas acting as an inert gas may also be supplied into the process chamber 201 from the rare gas supply tube 232c. That is, the argon (Ar) gas may be supplied into the process chamber 201 via the buffer chamber 237 while controlling the flow rate of the oxygen (O₂) gas by opening the valve 253c and using the mass flow controller 252c.

After the supply of the process gas is started, the high-frequency power source 273 applies high-frequency power, e.g., 50 W to 3000 W, and particularly, 200 W to 1000 W, to the tubular electrode 215 at a location at which a magnetic field is formed by the upper magnet 216a and the lower magnet 216b, via the impedance matching device 272. Thereby, magnetron discharge occurs in the process chamber 201, and high-density plasma is generated in the plasma generating region 224 above the wafer 200. In this case, the impedance control device 274 sets an impedance to a predetermined value.

As described above, even if the wafer 200 is heated to a low temperature, for example, 650° C. or less, the oxygen (O₂) gas supplied into the process chamber 201 is excited to be activated by generating plasma in the process chamber 201. Also, excited oxygen (O) atoms (hereinafter referred to as ‘oxygen radicals (O*)’ and/or ‘ionized oxygen atoms (O⁻)’) are supplied to the silicon oxide (SiO₂) film formed on the wafer 200.

By supplying the oxygen radicals (O*) and/or ionized oxygen atoms (O⁻) to the silicon oxide (SiO₂) film, impurities such as carbon (C) atoms, hydrogen (H) atoms, nitrogen (N) atoms and chlorine (Cl) atoms, may be removed from the silicon oxide (SiO₂) film. In other words, the energy of the oxygen radicals (O*) and/or ionized oxygen atoms (O⁻) is higher than the bonding energy of a chemical bond of Si—C, Si—H, Si—N and Si—Cl contained in the silicon oxide (SiO₂) film. Thus, the chemical bond of Si—C, Si—H, Si—N and Si—Cl is separated by applying the energy of the oxygen radicals (O*) and/or ionized oxygen atoms (O⁻) to the silicon oxide (SiO₂) film which is to be oxidized. N, H, Cl and C separated from Si are removed from the silicon oxide (SiO₂) film and are then discharged as N₂, H₂, Cl₂ and CO₂.

Also, by separating N, H, Cl and C from Si, the bonding electrons of the remaining Si are bonded with oxygen (O) atoms included in the oxygen radicals (O*) and/or ionized oxygen atoms (O⁻), thus forming a Si—O bond. Thus, the silicon oxide (SiO₂) film becomes dense.

Also, oxygen (O) atoms are supplemented to the silicon oxide (SiO₂) film in which oxygen (O) atoms are deficient by supplying the oxygen radicals (O*) and/or ionized oxygen atoms (O⁻) to the silicon oxide (SiO₂) film. Thus, since a composition ratio of the silicon oxide (SiO₂) film approximates a stoichiometric composition ratio, the silicon oxide (SiO₂) film nearly becomes a stoichiometric film. That is, the silicon oxide (SiO₂) film processed using a process sequence according to the present embodiment becomes a high-quality film, in which the concentration of impurities such as hydrogen (H), carbon (C), nitrogen (N) and chlorine (Cl) atoms, is very low and a ratio between the numbers of silicon atoms and oxygen atoms is substantially the same as ‘0.5’ which is the stoichiometric composition ratio. Accordingly, the silicon oxide (SiO₂) film may be modified as described above.

When a predetermined process time, e.g., one to five minutes, has passed and modification of the silicon oxide (SiO₂) film is completed, the supply of power to the tubular electrode 215 ends. Then, the valve 253a is closed to suspend the supply of O₂ gas into the process chamber 201.

### Purge Process (Operation S40)

After the modification (operation S30) is completed, exhaust is continuously performed by the gas exhaust tube 231 while the valve 243 is opened, thereby discharging a remnant gas from the process chamber 201. In other words, until the concentration of a process gas in the process chamber 201 becomes equal to or less than a predetermined value, the inside of the process chamber 201 is exhausted to discharge the remnant gas. For example, the inside of the process chamber 201 is exhausted until the concentration of the process gas becomes sufficient to unload the wafer 200 from the process chamber 201, i.e., until substrate unloading (operation S60). The inside of the process chamber 201 may be exhausted, for example, at least until the process gas is eliminated from the surface of the wafer 200. In this case, the valve 253c is opened and argon (Ar) gas acting as a purge gas is supplied into the process chamber 201 so as to expedite discharging of the remnant gas from the process chamber 201.

### Temperature Lowering/Atmospheric Pressure Recovery Process (Operation S50)

After the purge process (operation S40) is completed, the wafer 200 is lowered to a predetermined temperature, e.g., room temperature to 100° C., while adjusting the degree of opening of the APC 242 to return the pressure in the process chamber 201 to atmospheric pressure. In detail, the pressure in the process chamber 201 is raised to atmospheric pressure by supplying an inert gas, e.g., argon (Ar) gas, into the process chamber 201 while the valve 253c is opened, and adjusting the degree of opening the APC 242 and the valve 243 of the exhaust unit based on pressure information sensed by the pressure sensor. Then, the temperature of the wafer 200 is lowered by controlling the supply of power to the heater 217b.

### Substrate Unloading Process (S60)

Then, the susceptor 217 is lowered to a location at which the wafer 200 is to be transferred in order to support the wafer 200 on the wafer lift pins 266 protruding from the surface of the susceptor 217. Then, the gate valve 244 is opened to unload the wafer 200 from the process chamber 201 using the transfer mechanism, thereby completing the substrate processing according to the present embodiment. In the present embodiment, various conditions such as the temperature of the wafer 200, the pressure in the process chamber 201, the flow rate of each gas, the amount of power supplied to the tubular electrode 215, and a process time, may vary according to, for example, the material and thickness of the thin film to be modified.

### (3) Advantages of the Present Embodiment

According to the present embodiment, at least one among the following advantages can be achieved.

(a) According to the present embodiment, the wafer 200 is heated using the heater 217b, and a process gas supplied from the gas supply unit is excited by the excitation unit. When the excited process gas is supplied onto a surface of the wafer 200 to be processed, the temperature of the heater 217b is adjusted so that the temperature of the wafer 200 is less than or equal to the film-forming temperature of the thin film formed in advance on the wafer 200. Accordingly, the thin film formed on the wafer 200 at a low temperature may be modified at a low thermal budget. Also, impurities such as carbon (C) atoms, hydrogen (H) atoms and nitrogen (N) atoms, may be removed from the thin film.

(b) According to the present embodiment, a plasma generation electrode is used as the excitation unit. Thus, even if the temperature of the heater 217b configured to heat the wafer 200 is within a low-temperature range, the thin film formed on the wafer 200 may be modified, thereby improving the quality of the thin film. That is, impurities may be removed from the thin film formed on the wafer 200, a crystalline structure of the thin film may be improved, and defects of the thin film may be removed using the energy of plasma while suppressing a heating temperature of the wafer 200. Also, the thin film formed on the wafer 200 may be modified as a film having a stoichiometric composition ratio, i.e., a stoichiometric film.

(c) According to the present embodiment, the susceptor 217 for supporting the wafer 200 in the process chamber 201, the impedance control electrode 217c installed in the susceptor 217, and the impedance control device 274 connected to the impedance control electrode 217c in order to control an electric potential of the wafer 200 by adjusting an impedance of the impedance control electrode 217c are used. By controlling the impedance control device 274 configured as described above and the excitation unit, an electric field perpendicular to the wafer 200 may become stronger than an electric field parallel to the wafer 200 or vice versa when an excited process gas is supplied onto the wafer 200 to be processed. Thus, a corrugated structure having a predetermined shape such as a MOS transistor gate structure or a DRAM capacitor structure, may be formed in advance on a surface of the thin film formed on the wafer 200, which is to be processed. Convex portions of the corrugated structure may be disposed apart from one another by, for example, a distance of 10 to 50 nm. Also, if the length between upper and lower ends of each of concave portions of the corrugated structure is longer than the distance between the convex portions, the concave portions may have a high aspect ratio.

That is, when the wafer 200 having a corrugated structure thereon is processed, the surfaces of the corrugated structure of the wafer 200 may not be evenly processed. For example, sidewall portions of concave portions of the wafer 200 may be processed later than lower portions of the concave portions. According to the present embodiment, for example, the impedance control device 274 may be controlled to have a predetermined impedance so that the electric field parallel to the wafer 200 becomes stronger than the electric field perpendicular to the wafer 200, thereby increasing the speed of processing the sidewall portions of the concave portions. Also, for example, the speed of processing the wafer 200 in a vertical direction may be set to be higher than that of processing the wafer 200 in a horizontal direction. As described above, the surfaces of the corrugated structure may be evenly processed by appropriately controlling the speeds of processing the lower and sidewall portions of each concave portion (the speeds of processing the wafer 200 in the horizontal and vertical directions). Furthermore, by generating plasma in the process chamber 201, excited oxygen gas may be supplied to the lower and sidewall portions of each concave portion. Also, by generating magnetron plasma in the process chamber 201, excited oxygen gas may be supplied to the lower and sidewall portions of each concave portion.

(d) According to the present embodiment, the film-forming temperature of the thin film formed on the wafer 200 is set to be equal to or lower than 650° C., for example, 450° C. Also, the temperature of the heater 217b configured to heat the wafer 200 including the thin film is set to be less than or equal to the film-forming temperature of the thin film, for example, 450° C. Thus, substrate processing (modification) may be performed while suppressing thermal stress on the thin film formed on the wafer 200.

### Other Embodiments

An embodiment of the present invention has been described above, but the present invention is not limited thereto and various changes may be made in form and details without departing from the spirit and scope of the invention as defined by the appended claims.

In the above-described embodiment, a thin film is formed on the wafer 200 by CVD at low temperature, for example, equal to or lower than 650° C., but the present invention is not limited thereto. In other words, the thin film may be formed on the wafer 200, for example, using plasma CVD, high-temperature CVD (a high-temperature oxide (HTO)), high-temperature thermal treatment (annealing), or atomic layer deposition (ALD). Coverage characteristics of a film formed by HTO are known to be bad.

Also, the above-described embodiment has been described with respect to a case in which a silicon oxide (SiO₂) film is formed in advance on the wafer 200 at a predetermined film-forming temperature. However, the present invention is not limited thereto, and for example, a nitride film such as a SiN film, may be formed on the wafer 200 at a predetermined film-forming temperature. In this case, at least nitrogen-containing gas (e.g., N₂ gas) may be supplied as a process gas into the process chamber 201. That is, as illustrated in FIG. 1, first, the valve 253b is opened, and the N₂ gas is supplied as the process gas into the process chamber 201 via the buffer chamber 237 using the nitrogen-containing gas supply tube 232b. In this case, the degree of opening of the mass flow controller 252b is adjusted in such a manner that the flow rate of the N₂ gas may be equal to a predetermined flow rate. Since nitrogen radicals (N*) have high energy, impurities such as hydrogen (H), carbon (C) and chlorine (Cl) atoms, may be separated and discharged from the SiN film. Also, nitrogen (N) atoms are bonded with a dangling bond generated when the impurities are separated from the SiN film, and nitriding of the SiN film is promoted, thereby greatly improving the quality of the SiN film. Also, diffusion of impurities may be prevented by introducing nitrogen (N) atoms into the SiN film. Thus, even when a nitride film has been formed on the wafer 200, the advantages according to the previous embodiment as described above may be achieved.

Also, for example, an oxynitride film, e.g., a SiON film, may be formed in advance on the wafer 200 at a predetermined film-forming temperature. In this case, a gas containing oxygen (O) and nitrogen (N) atoms, for example, nitric oxide (NO) gas or nitrous oxide (N₂O) gas, may be supplied as a process gas into the process chamber 201. Thus, the advantages described above may be achieved by removing impurities from an oxynitride film. Also, a gas containing oxygen (O) and nitrogen (N) atoms, for example, nitric oxide (NO) gas or nitrous oxide (N₂O) gas, may be used as a process gas for modifying a silicon oxide (SiO₂) film formed in advance on the wafer 200. Although the capabilities of these gases for removing the silicon oxide (SiO₂) film are lower than that of oxygen (O₂) gas, these gases may be used to remove impurities from a film formed at a low temperature.

Also, the above-described embodiment has been described with respect to a case in which oxygen (O₂) gas is used as an oxygen-containing gas, but the present invention is not limited thereto. Annealing may be performed using ozone (O₃) gas or vapor (H₂O) as long as thermal treatment is performed at a temperature equal to or lower than a film-forming temperature of a thin film formed on the wafer 200. Alternatively, annealing may be performed by supplying oxygen (O₂) gas or hydrogen (H) gas into the process chamber 201, or Batch Isotropic Oxidation (BIO) treatment may be performed.

Also, in the above-described embodiment, a silicon oxide (SiO₂) film is formed in advance on the wafer 200 using TEOS which is a film-forming gas containing an organic source gas. However, the present invention is not limited thereto, and for example, a thin film including at least one among hydrogen (H), carbon (C), nitrogen (N) and chlorine (Cl) atoms may be formed on the wafer 200 using a film-forming gas containing an organic source gas, e.g., DCS or TSA. In this case, an amount of impurities contained in the thin film may be reduced by processing the thin film as described above.

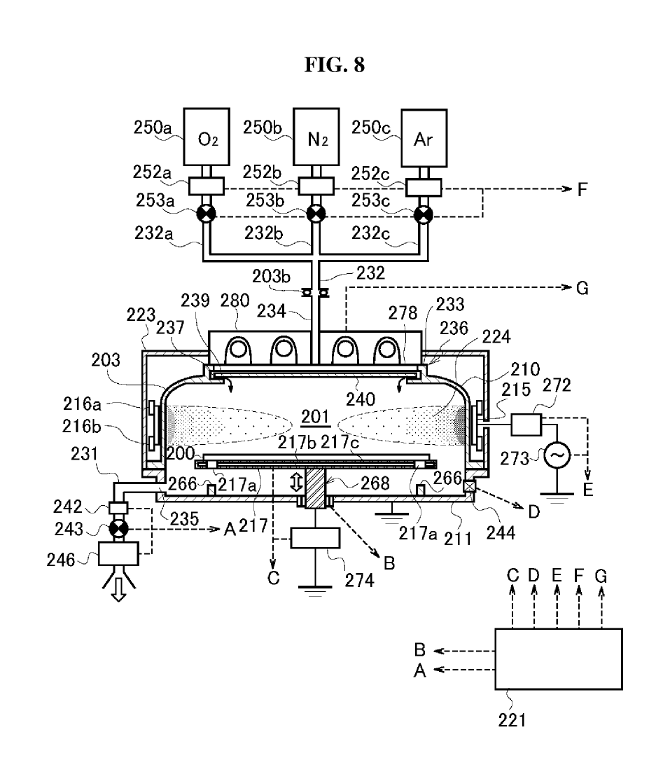

Also, in the above-described embodiment, the wafer 200 is heated using the heater 217b installed in the susceptor 217, but the present invention is not limited thereto. Alternatively, the wafer 200 may be heated by irradiating infrared light or the like thereon using a lamp heating unit 280 as illustrated in FIG. 8. In this case, the lamp heating unit 280 may be configured to irradiate light into the process chamber 201 via a light transmission window 278 installed above the process chamber 201, i.e., on a surface of the upper container 210. Otherwise, the temperature of the wafer 200 may be raised more quickly when using the heater 217b and the lamp heating unit 280 together than when using only the heater 217b. Also, the wafer 200 may be heated using only the lamp heating unit 280 without installing the heater 217b. The lamp heating unit 280 is configured to be controlled by the controller 221 via a signal line G.

Also, the above-described embodiment has been described with respect to a case in which the substrate processing apparatus 100 which is an MMT device is used. However, the present invention is not limited thereto, and any of other devices, e.g., an inductively-coupled plasma (ICP) device or an electron cyclotron resonance (ECR) device, may be used.

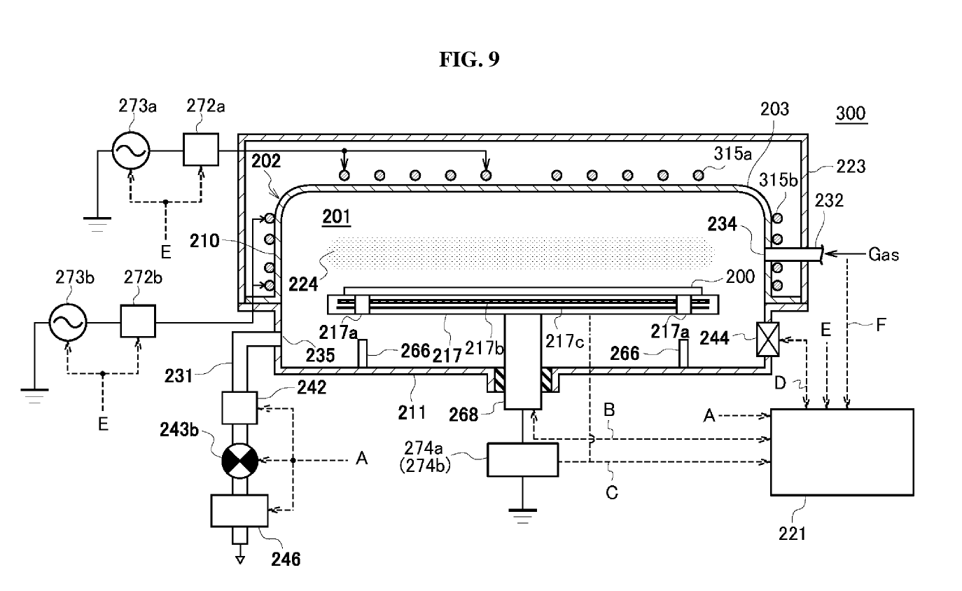

FIG. 9 is a schematic cross-sectional view of an ICP-based plasma processing apparatus 300 which is a substrate processing apparatus according to another embodiment of the present invention. For convenience of explanation, elements of the ICP-based plasma processing apparatus 300 that are the same as those of the substrate processing apparatus 100 according to the previous embodiments will now be denoted by the same reference numerals. Also, structures and operations of a gas supply unit will not be described again herein. In the ICP-based plasma processing apparatus 300 according to the present embodiment, plasma is generated by supplying power to high-frequency power sources 273a and 273b via impedance matching devices 272a and 272b and dielectric coils 315a and 315b, respectively. The dielectric coil 315a is installed at an outer side of a ceiling of the process container 203. The dielectric coil 315b is installed at an outer side of a circumferential wall of the process container 203. In the present embodiment, a process gas containing at least one of oxygen and nitrogen atoms is supplied into a process chamber 201 via a gas introduction unit 234 using a gas supply tube 232. Also, before and after the process gas is supplied, an electric field is generated by electromagnetic induction by supplying high-frequency power to the dielectric coils 315a and 315b which are excitation units. Active species may be generated by exciting the supplied process gas to a plasma state using the electric field as energy.

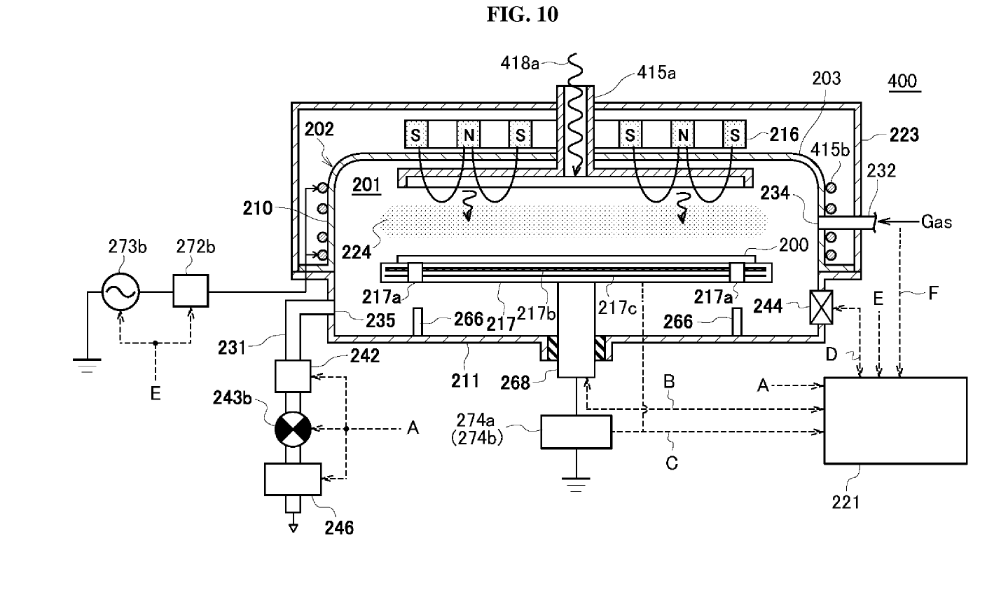

FIG. 10 illustrates an ECR-based plasma processing apparatus 400 which is a substrate processing apparatus according to still another embodiment of the present invention. For convenience of explanation, elements of the ICP-based plasma processing apparatus 300 that are the same as those of the substrate processing apparatus 100 according to the previous embodiments will now be denoted by the same reference numerals. Also, structures and operations of a gas supply unit will not be described again herein. The ECR-based plasma processing apparatus 400 according to the present embodiment includes a high-frequency power source 273b which supplies microwaves to generate plasma, an impedance matching device 272b, a microwave introduction tube 415a and a dielectric coil 415b. The microwave introduction tube 415a is installed on a ceiling wall of a process container 203. The dielectric coil 415b is installed at an outer side of a circumferential wall of the process container 203. In the present embodiment, a process gas containing at least one of oxygen and nitrogen atoms is also supplied into a process chamber 201 via a gas introduction unit 234 using the gas supply tube 232. Also, before and after the process gas is supplied, microwaves 418a are introduced into the microwave introduction tube 415a and are emitted to the process chamber 201. Active species may be generated by exciting the supplied process gas to a plasma state using high-frequency power generated by the microwaves 418a and the dielectric coil 415b. For example, variable-frequency microwaves (VFM), fixed-frequency microwaves (FFM), or the like may be used as the microwaves 418a.

In addition, modification may be performed on a thin film formed on a wafer 200 by irradiating ultraviolet rays on the thin film using a rapid thermal processing (RTP) device.

### Examples

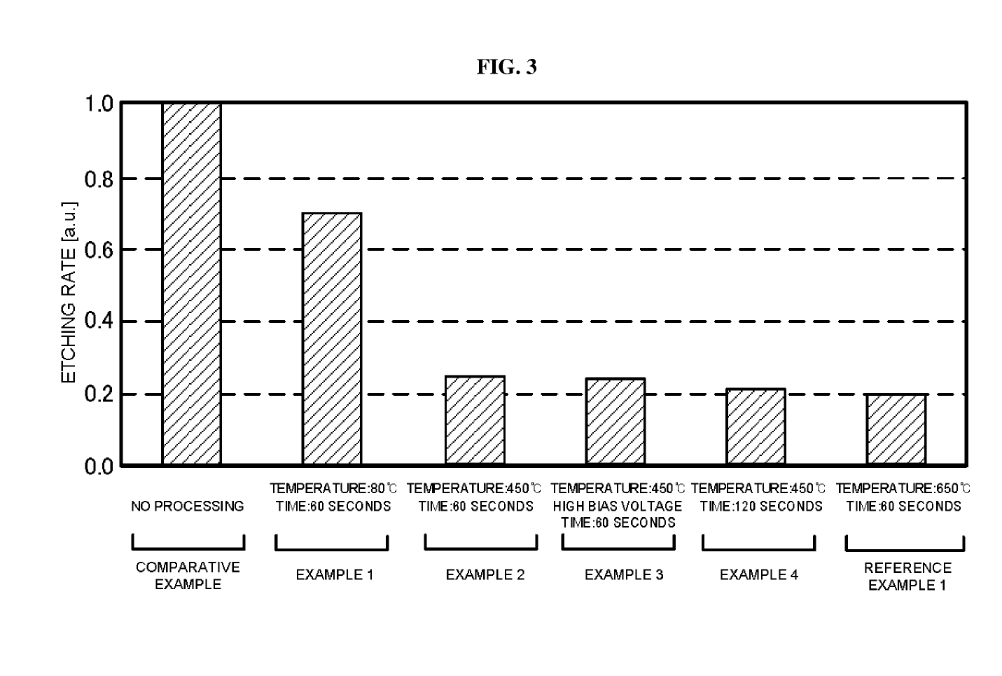

Next, examples of the present invention will be described with reference to FIGS. 3 through 7. A case in which substrate processing, i.e., modification, in one example of the present invention is performed using TEOS as a film-forming gas, using a wafer 200 on which a SiO₂ film has been formed at a film-forming temperature of 450° C. within a low-temperature range, and by supplying oxygen (O₂) gas excited by a plasma generation electrode to the wafer 200 will be described.

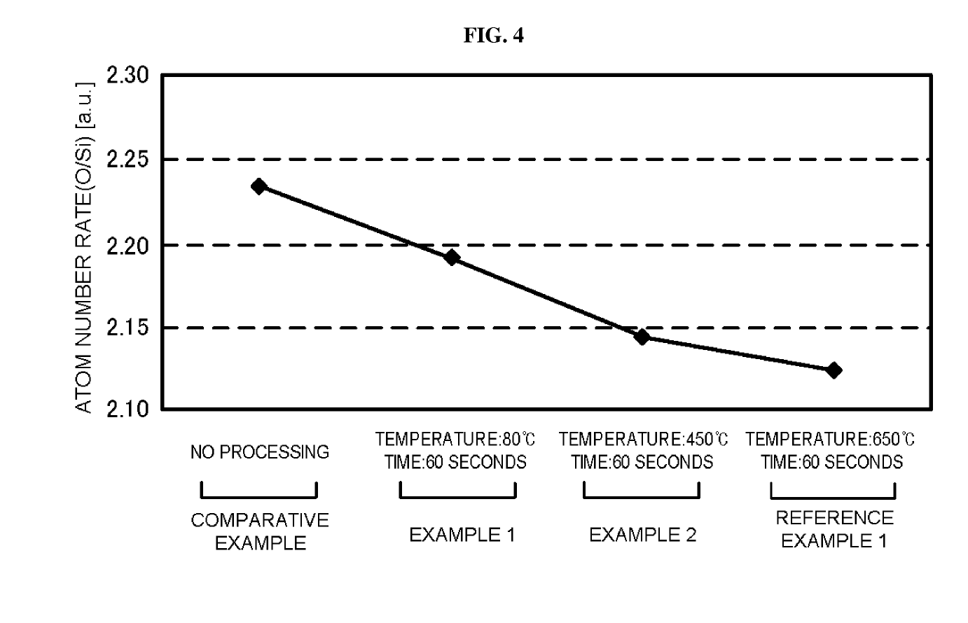

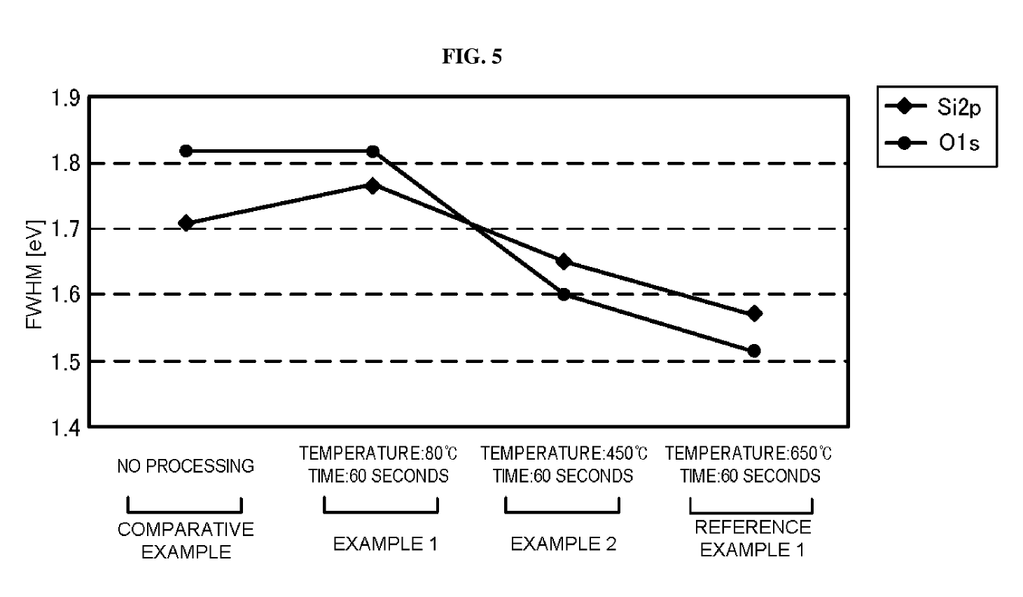

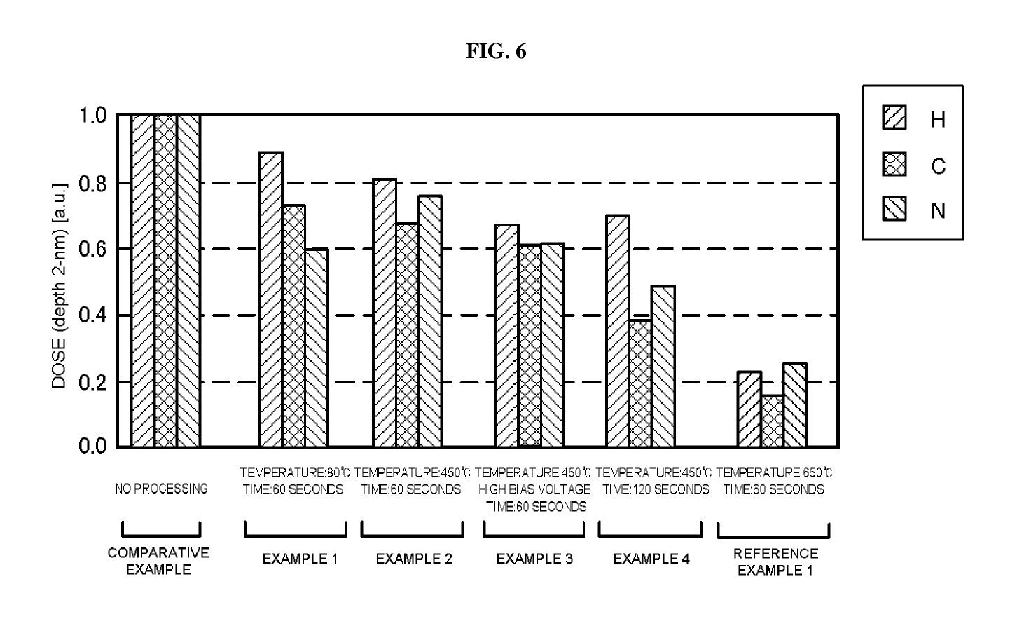

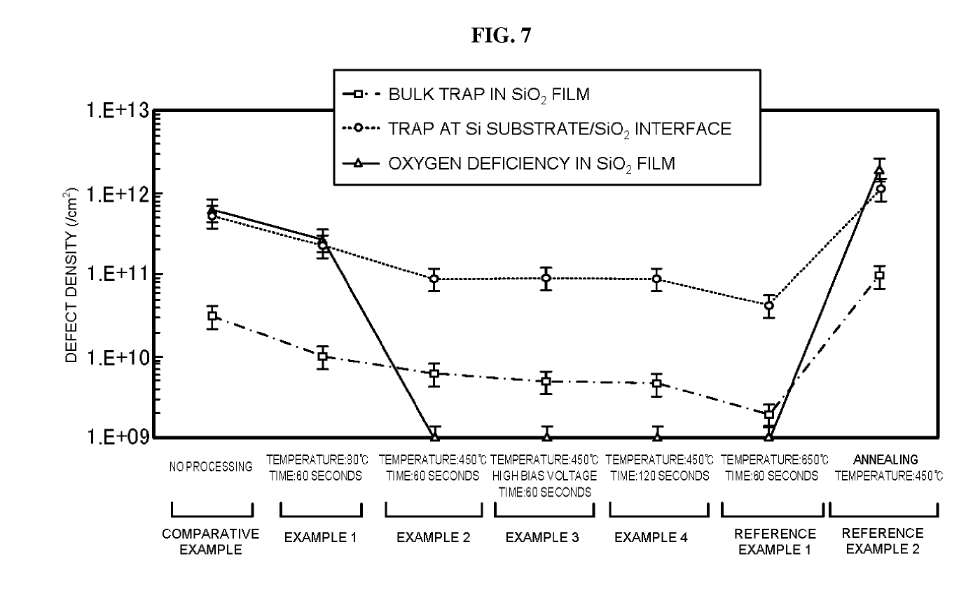

FIG. 3 is a graph illustrating a result of evaluating an etching rate of a silicon oxide (SiO₂) film in which modification is performed under various conditions when etching was performed using dilute hydrofluoric acid (DHF). FIG. 4 is a graph illustrating a ratio between the numbers of oxygen atoms and silicon atoms obtained by analyzing a silicon oxide (SiO₂) film on a substrate-processed wafer through X-ray photoelectron spectroscopy (XPS) under various conditions. FIG. 5 is a graph illustrating a full width at half maximum of a peak value of each of 2p orbital of silicon atoms and 1s orbital of oxygen atoms, obtained by analyzing a silicon oxide (SiO₂) film on a substrate-processed wafer through XPS under various conditions. FIG. 6 is a graph illustrating the concentration of impurities contained in a silicon oxide (SiO₂) film obtained by measuring a wafer on which the silicon oxide (SiO₂) film is formed through SIMS. FIG. 7 is a graph illustrating the defect density of a silicon oxide (SiO₂) film formed on a wafer under various conditions.

In FIGS. 3 through 7, “temperature: 80° C., time: 60 seconds” denotes a case in which the wafer 200 was modified by heating the wafer 200 to 80° C. and supplying a process gas for 60 seconds (Example 1). “Temperature: 450° C., time: 60 seconds” denotes a case in which the wafer 200 was modified by heating the wafer 200 to 450° C., which is substantially equal to a film-forming temperature of the silicon oxide (SiO₂) film, and supplying the process gas for 60 seconds (Example 2). “Temperature: 450° C., high bias voltage, time: 60 seconds” denotes a case in which the wafer 200 was modified by heating the wafer 200 to 450° C., setting a bias voltage to be higher than in the other examples, and supplying the process gas for 60 seconds (Example 3). “Temperature: 450° C., time: 120 seconds” denotes a case in which the wafer 200 was modified by heating the wafer 200 to 450° C. and supplying the process gas for 60 seconds (Example 4).

“Temperature: 650° C., time: 60 seconds” denotes a case in which the wafer 200 was modified by heating the wafer 200 to 650° C., which is higher than the film-forming temperature of the silicon oxide (SiO₂) film, and supplying the process gas for 60 seconds (Reference Example 1). Also, in FIG. 7, “annealing, temperature: 450° C.” denotes a case in which the wafer 200 was modified by annealing the wafer 200 at 450° C. without exciting oxygen (O₂) gas (Reference Example 2).

Also, “no processing” denotes a case in which the wafer 200 was not modified (Comparative Example).

Referring to FIG. 3, an etching rate in Comparative example was ‘1.0,’ whereas the etching rate in Example 1 was about ‘0.8’ times higher than in Comparative example. In Example 2, the etching rate was about ‘0.2’ times higher than in Comparative example. In Example 3, the etching rate was about ‘0.2’ times higher than in Comparative example and was substantially the same as in Example 2. In Example 4, the etching rate was about ‘0.2’ times higher than in Comparative example but was slightly higher than in Examples 2 and 3. Even when the wafer 200 was modified by setting the temperature of the wafer 200 to be higher than the film-forming temperature as in Reference Example 1, the etching rate was substantially the same, particularly compared to Examples 2 through 4. Thus, it is concluded that when the wafer 200 is modified, the heating temperature of the wafer 200 may be set to be equal to or lower than the film-forming temperature of the thin film formed on the wafer 200, and may be preferably set to be substantially the same as the film-forming temperature.

FIG. 4 shows the ratio between the numbers of silicon (Si) atoms and oxygen (O) atoms contained in the resultant silicon oxide (SiO₂) film after modification was performed on the silicon oxide (SiO₂) film formed on the wafer 200. That is, compared to Comparative example, in the case of Examples 1 and 2 and Reference Example 1 in which modification was performed, the ratio between the numbers of silicon (Si) atoms and oxygen (O) atoms was substantially the same as an ideal stoichiometric ratio (Si:O=1:2) of SiO₂ and a crystalline structure of the silicon oxide (SiO₂) was substantially the same as a stoichiometric structure. Since the amount of the silicon (Si) atoms is considered not to be changeable, the above result was due to a reduction in the amount of surplus oxygen (O) atoms. Also, when oxygen (O) atoms are deficient in the silicon oxide (SiO₂) film that has yet to be modified, the ratio between the numbers of the silicon (Si) atoms and the oxygen (O) atoms may become substantially the same as the ideal stoichiometric ratio (Si:O=1:2) of SiO₂ by supplying oxygen (O) atoms.

FIG. 5 is a graph illustrating a full width at half maximum (FWHM) of a peak value of each of 2p orbital of silicon atoms and 1s orbital of oxygen atoms measured through X-ray photoelectron spectroscopy (XPS). As FWHM is small, a crystalline structure is more stable. That is, a lower FWHM indicates a better bonding state of a silicon oxide (SiO₂) film after the silicon oxide (SiO₂) film is modified. Referring to FIG. 5, the 2p orbital of silicon (Si) had an FWHM of about 1.7 and the is orbital of oxygen (O) had an FWHM of about 1.8 in Comparative example, whereas the 2p orbital of silicon (Si) had an FWHM of about 1.65 and the 1s orbital of oxygen (O) had an FWHM of about 1.6 in Example 2 in which modification was performed at a film-forming temperature of a silicon oxide (SiO₂) film. Thus, in Example 2, a crystalline structure of the silicon oxide (SiO₂) was stable, thus forming a high-quality oxide film. Also, since the FWHM in Reference Example is lower than in Example 2, the crystalline structure of the silicon oxide (SiO₂) film that is modified is more stable than in Example 2.

FIG. 6 illustrates doses in a depth of 2 nm to 8 nm, measured through SIMS. Particularly, FIG. 6 illustrates a relative ratio between the doses of various atoms according to Examples 1 through 4 and Reference Example 1 when the dose of each of hydrogen (H) atoms, carbon (C) atoms and nitrogen (N) atoms contained in a thin film according to Comparative example was ‘1.0.’ Referring to FIG. 6, the amounts of impurities in Examples 1 through 4 and Reference Example 1 in which modification was performed using plasma were smaller than in Comparative example in which modification was not performed. In other words, for example, in Example 2, the doses of hydrogen (H) atoms, carbon (C) atoms and nitrogen (N) atoms contained in the silicon oxide (SiO₂) film that was modified were about 0.8 times, about 0.7 times and about 0.75 times those of Comparative example, respectively. As described above, the amount of impurities in the silicon oxide (SiO₂) film that was modified using plasma decreased and the quality of the silicon oxide (SiO₂) film was thus improved, thereby improving device characteristics.

FIG. 7 is a graph illustrating the defect density of a silicon oxide (SiO₂) film formed on a wafer 200. That is, FIG. 7 illustrates the trap density of the silicon oxide (SiO₂) film measured through electrical detection ESR. The defect density may be used as the index for improving device characteristics. Electrical detection ESR is a measuring method, the measuring sensitivity or precision of which is improved compared to that of general ESR by adding atom spin manipulation using microwaves to general ESR. Also, in FIG. 7, “bulk trap in the silicon oxide (SiO₂) film” indicates a result of measuring defects in the silicon oxide (SiO₂) film, “trap at interface between Si substrate/SiO₂” indicates a result of measuring defects occurring at the interface between the wafer 200 and the silicon oxide (SiO₂) film, and “oxygen deficiency in the silicon oxide (SiO₂) film” indicates a result of measuring hole defects caused when the silicon (Si) atoms and oxygen (O) atoms in the silicon oxide (SiO₂) film are not bonded with one another. Referring to FIG. 7, the trap density in the silicon oxide (SiO₂) film formed on the wafer 200 was reduced by performing modification thereon using plasma. That is, the bulk trap in the silicon oxide (SiO₂) film was about 3×10¹⁰ Comparative example, but was reduced to about 6×10⁹ in Example 2. Also, the trap at an interface between the Si substrate/SiO₂ was about 5×10¹¹ in Comparative example, but was reduced to about 1×10¹¹ in Example 2. Also, the oxygen deficiency in the silicon oxide (SiO₂) film was about 7×10¹¹ in Comparative example, but was reduced to the lower limit of detection in Example 2. Also, Reference Example 2 shows that the wafer 200 was modified by performing annealing (thermal treatment) at 450° C. without using plasma treatment. In Reference example 2, when the silicon oxide (SiO₂) film was annealed at 450° C. without exciting oxygen (O₂) gas, the trap density in the silicon oxide (SiO₂) film was not improved. Thus, when modification is performed on the silicon oxide (SiO₂) film formed at 450° C. that is a film-forming temperature within a low-temperature range, not only heating temperature but also plasma treatment is important. Also, defects occurring in the silicon oxide (SiO₂) film were reduced by plasma treatment. Thus, it is expected that an amount of leaking current in a device will be reduced, thereby improving characteristics of the device.

Referring to FIGS. 3 through 7, a result of modifying the silicon oxide (SiO₂) film was best in Reference Example 1. However, as shown in Reference Example 1, when modification is performed at temperature higher than the film-forming temperature of the silicon oxide (SiO₂) film, defects may occur due to thermal budgets or the like. Also, even if modification is performed at a temperature lower than a film-forming temperature (within a low-temperature range) of a thin film formed on the wafer 200 as in Examples 1 through 4, impurities contained in the thin film may be removed. In particular, referring to the etching rates obtained using dilute hydrofluoric acid (DHF) illustrated in FIG. 3, which indicate advantages achieved by performing modification according to the present invention, a result of performing modification at a temperature that is the same as the film-forming temperature of the thin film as in Examples 2 through 4 is not greatly different than in Reference Example 1, and problems occurring due to thermal budgets may be prevented.

### Exemplary Embodiments

Exemplary embodiments of the present invention will now be described.

According to an embodiment of the present invention, there is provided a substrate processing apparatus including: a process chamber accommodating a substrate including a thin film formed at a predetermined film-forming temperature; a gas supply unit configured to supply a process gas including at least one of oxygen and nitrogen to the substrate in the process chamber; an excitation unit configured to excite the process gas supplied into the process chamber; a heating unit configured to heat the substrate in the process chamber; an exhaust unit configured to exhaust an inside of the process chamber; and a control unit configured to control at least the gas supply unit, the excitation unit, the heating unit and the exhaust unit in a manner that a temperature of the substrate is equal to or lower than the film-forming temperature when the substrate is processed by heating the substrate by the heating unit, exciting the process gas supplied from the gas supply unit by the excitation unit, and supplying the process gas excited by the excitation unit to a surface of the substrate.

It is preferable that the substrate processing apparatus further includes: a substrate support installed in the process chamber to support the substrate; an impedance control electrode installed in the substrate support; and an impedance control device connected to the impedance control electrode and configured to adjust an electric potential of the substrate by adjusting an impedance of the impedance control electrode, wherein the control unit controls the impedance control device and the excitation unit such that an electric field perpendicular to the substrate is stronger than an electric field parallel to the substrate or the electric field parallel to the substrate is stronger than the electric field perpendicular to the substrate when the substrate is processed by supplying the process gas excited by the excitation unit to the substrate.

Further, it is preferable that the thin film includes one of an oxide film, a nitride film and an oxynitride film.

Further, it is preferable that a surface of the thin film includes a corrugated structure having a predetermined shape.

Further, it is preferable that the excitation unit includes at least a plasma generation electrode.

Further, it is preferable that the film-forming temperature is equal to or lower than 650° C.

Further, it is preferable that the thin film includes at least one of a hydrogen atom, a carbon atom, a nitrogen atom and a chlorine atom.

According to another embodiment of the present invention, there is provide a method of manufacturing a semiconductor device, including: loading a substrate into a process chamber, the substrate having a thin film thereon formed at a predetermined film-forming temperature; and processing the substrate by heating the substrate to a temperature equal to or lower than the predetermined film-forming temperature, supplying a process gas including at least one of oxygen and nitrogen into the process chamber while exhausting an inside of the process chamber, exciting the process gas supplied into the process chamber, and supplying the excited process gas to a surface of the substrate.

According to another embodiment of the present invention, there is provided a method of manufacturing a substrate, including: loading a substrate into a process chamber, the substrate having a thin film thereon formed at a predetermined film-forming temperature; and processing the substrate by heating the substrate to a temperature equal to or lower than the predetermined film-forming temperature, supplying a process gas including at least one of oxygen and nitrogen to the substrate, and exciting the process gas supplied to the substrate.

According to still another embodiment of the present invention, there is provided a program for causing a computer to execute: loading a substrate into a process chamber, the substrate having a thin film thereon formed at a predetermined film-forming temperature; and processing the substrate by heating the substrate to a temperature equal to or lower than the predetermined film-forming temperature, supplying a process gas including at least one of oxygen and nitrogen to the substrate while exhausting an inside of the process chamber, exciting the process gas supplied to the substrate, and supplying the excited process gas to a surface of the substrate to process the substrate.

According to still another embodiment of the present invention, there is provided a program for causing a computer to execute: heating a substrate accommodated in a process chamber having thereon a thin film formed at a predetermined film-forming temperature to a temperature equal to or lower than the predetermined film-forming temperature; supplying a process gas including at least one of oxygen and nitrogen to the substrate; and exciting the process gas supplied to the substrate.

According to still another embodiment of the present invention, there is provided a non-transitory computer-readable recording medium having a program to be executed by a computer: heating a substrate accommodated in a process chamber having thereon a thin film formed at a predetermined film-forming temperature to a temperature equal to or lower than the predetermined film-forming temperature; supplying a process gas including at least one of oxygen and nitrogen to the substrate; and exciting the process gas supplied to the substrate; and an exhausting step for exhausting an inside of the process chamber.

According to another embodiment of the present invention, there is provided an apparatus for manufacturing a semiconductor device, including: a process chamber accommodating a substrate including a thin film formed at a predetermined film-forming temperature; a gas supply unit configured to supply a process gas including at least one of oxygen and nitrogen to the substrate in the process chamber; an excitation unit configured to excite the process gas supplied into the process chamber; a heating unit configured to heat the substrate in the process chamber; an exhaust unit configured to exhaust an inside of the process chamber; and a control unit configured to control at least the gas supply unit, the excitation unit, the heating unit and the exhaust unit in a manner that a temperature of the substrate is equal to or lower than the film-forming temperature when the substrate is processed by heating the substrate by the heating unit, exciting the process gas supplied from the gas supply unit by the excitation unit, and supplying the process gas excited by the excitation unit to a surface of the substrate.

What is claimed is:

1. A substrate processing apparatus comprising:
a process chamber accommodating a substrate including a thin film formed at a predetermined film-forming temperature;
a gas supply unit configured to supply a process gas including at least one of oxygen and nitrogen to the substrate in the process chamber;
an excitation unit configured to excite the process gas supplied into the process chamber;
a heating unit configured to heat the substrate in the process chamber;
an exhaust unit configured to exhaust an inside of the process chamber; and
a control unit configured to control at least the gas supply unit, the excitation unit, the heating unit and the exhaust unit in a manner that a temperature of the substrate is equal to or lower than the film-forming temperature when the substrate is processed by heating the substrate by the heating unit, exciting the process gas supplied from the gas supply unit by the excitation unit, and supplying the process gas excited by the excitation unit to a surface of the substrate.

2. The substrate processing apparatus of claim 1, further comprising:
a substrate support installed in the process chamber to support the substrate;
an impedance control electrode installed in the substrate support; and
an impedance control device connected to the impedance control electrode and configured to adjust an electric potential of the substrate by adjusting an impedance of the impedance control electrode,
wherein the control unit controls the impedance control device and the excitation unit such that an electric field perpendicular to the substrate is stronger than an electric field parallel to the substrate or the electric field parallel to the substrate is stronger than the electric field perpendicular to the substrate when the substrate is processed by supplying the process gas excited by the excitation unit to the substrate.

3. The substrate processing apparatus of claim 1, wherein the thin film comprises one of an oxide film, a nitride film and an oxynitride film.

4. The substrate processing apparatus of claim 1, wherein a surface of the thin film comprises a corrugated structure having a predetermined shape.

5. The substrate processing apparatus of claim 1, wherein the excitation unit comprises at least a plasma generation electrode.

6. The substrate processing apparatus of claim 5, wherein the control unit controls the plasma generation electrode so as to generate magnetron discharge in the process chamber.

7. The substrate processing apparatus of claim 1, wherein the film-forming temperature is equal to or lower than 650° C.

8. The substrate processing apparatus of claim 1, wherein the thin film comprises at least one of a hydrogen atom, a carbon atom, a nitrogen atom and a chlorine atom.

9. A method of manufacturing a semiconductor device, comprising:
loading a substrate into a process chamber, the substrate having a thin film thereon formed at a predetermined film-forming temperature; and
processing the substrate by
heating the substrate to a temperature equal to or lower than the predetermined film-forming temperature,
supplying a process gas including at least one of oxygen and nitrogen to the substrate, and
exciting the process gas supplied to the substrate.

10. The method of claim 9, wherein the thin film comprises one of an oxide film, a nitride film and an oxynitride film.

11. The method of claim 9, wherein a surface of the thin film comprises a corrugated structure having a predetermined shape.

12. The method of claim 9, wherein the thin film comprises at least one of a hydrogen atom, a carbon atom, a nitrogen atom and a chlorine atom.

13. The method of claim 9, wherein the exciting of the process gas comprises generating magnetron discharge in the process chamber.

14. A non-transitory computer-readable recording medium having a program to be executed by a computer:
heating a substrate accommodated in a process chamber having thereon a thin film formed at a predetermined film-forming temperature to a temperature equal to or lower than the predetermined film-forming temperature; and
processing the substrate by
supplying a process gas including at least one of oxygen and nitrogen to the substrate, and
exciting the process gas supplied to the substrate.

15. The non-transitory computer-readable recording medium of claim 14, wherein the thin film comprises one of an oxide film, a nitride film and an oxynitride film.

16. The non-transitory computer-readable recording medium of claim 14, wherein a surface of the thin film comprises a corrugated structure having a predetermined shape.

17. The non-transitory computer-readable recording medium of claim 14, wherein the thin film comprises at least one of a hydrogen atom, a carbon atom, a nitrogen atom and a chlorine atom.

18. The non-transitory computer-readable recording medium of claim 14, wherein the exciting of the process gas comprises generating magnetron discharge in the process chamber.
